(19) United States
(12) Patent Application Publication
(10) Pub. No.: US 2023/0326232 A1
(43) Pub. Date: Oct. 12, 2023

(54) FINGERPRINT SENSING APPARATUS

(71) Applicant: Egis Technology Inc., Hsinchu City (TW)

(72) Inventor: Shiue-Shin Liu, Hsinchu City (TW)

(73) Assignee: Egis Technology Inc., Hsinchu City (TW)

(21) Appl. No.: 17/769,328

(22) PCT Filed: Jul. 30, 2020
(86) PCT No.: PCT/CN2020/105846

§ 371 Date: Apr. 14, 2022

Related U.S. Application Data
(60) Provisional application No. 62/948,807, filed on Dec. 17, 2019.
(60) Provisional application No. 63/006,736, filed on Apr. 8, 2020.

(51) Int. Cl. G06V 40/13; H03M 1/12

(52) U.S. Cl. CPC G06V 40/1318; H03M 1/12

(57) ABSTRACT

The present disclosure provides a fingerprint sensing apparatus. A sensing pixel array comprises a plurality of sensing pixels; and each sensing pixel senses an optical signal comprising fingerprint information, and according to the optical signal and an operation voltage, generates a sensing signal. A control circuit adjusts the voltage value of the operation voltage according to the sensing signal, so that the voltage value of the sensing signal generated by each sensing pixel falls within a default range. An analog-to-digital conversion circuit converts the sensing signal into a digital signal.

### BACKGROUND

### Technical Field

The disclosure relates to a sensing apparatus, and in particular relates to a fingerprint sensing apparatus.

### Description of Related Art

In recent years, the biological identification technology has developed rapidly. Since security codes and access cards are easily stolen or lost, the fingerprint identification technology attracts more attention. Fingerprints are unique and constant, and every person has multiple fingers for identification. Furthermore, a fingerprint sensor can be used to easily obtain a fingerprint. Therefore, the fingerprint identification can improve security and convenience, and can better protect financial security and confidential data.

A thin film transistor (TFT) fingerprint sensor can be used to realize the full-screen fingerprint recognition in a large area. However, due to the characteristics of a thin film transistor such as large changes in the threshold voltage and high conductive resistance, coupled with die-to-die variation, temperature, aging and other factors, excessive voltage changes in the fingerprint sensing signal may easily occur. Since the input range of the analog digital converter is limited, excessive voltage changes tend to greatly reduce the available dynamic range, which makes the manufacturers have no choice but to use a high-resolution analog digital converter, and thus greatly increases the production cost of fingerprint sensors.

### SUMMARY

The disclosure provides a fingerprint sensing apparatus, which can adjust a varying range of a sensing signal output to analog-to-digital conversion circuits and reduce the requirement for a dynamic range of the analog-to-digital conversion circuits, thereby effectively avoid increasing the production cost of the fingerprint sensing apparatus.

The fingerprint sensing apparatus of the disclosure includes a sensing pixel array, a control circuit, and multiple analog-to-digital conversion circuits. The sensing pixel array includes multiple sensing pixels, and each of the sensing pixels is coupled to an operation voltage. Each of the sensing pixels senses an optical signal including fingerprint information, and generates a sensing signal according to the optical signal and the operation voltage. The control circuit is coupled to the sensing pixel array, and adjusts a voltage value of the operation voltage according to the sensing signal to enable a voltage value of the sensing signal generated by each of the sensing pixels to fall within a default range. The analog-to-digital conversion circuits are individually coupled to the corresponding sensing pixels through multiple corresponding sensing signal lines to convert the sensing signal into a digital signal.

Based on the above, the control circuit in the embodiment of the disclosure may adjust the voltage value of the operation voltage output to each of the sensing pixels according to the sensing signal to enable the voltage value of the sensing signal generated by each of the sensing pixels to fall within the default range. In this way, the requirement for the dynamic range of the analog-to-digital conversion circuits can be reduced, and the production cost of the fingerprint sensing apparatus can be effectively avoided from increasing.

To make the aforementioned more comprehensible, several embodiments accompanied with drawings are described in detail as follows.

### BRIEF DESCRIPTION OF THE DRAWINGS

FIG. 1 is a schematic view of a fingerprint sensing apparatus according to an embodiment of the disclosure.

FIG. 2 is a schematic view of a sensing pixel according to an embodiment of the disclosure.

FIG. 3 is a schematic view of a fingerprint sensing apparatus according to another embodiment of the disclosure.

FIG. 4 is a schematic view of a fingerprint sensing apparatus according to another embodiment of the disclosure.

FIG. 5 is a schematic view of a fingerprint sensing apparatus according to another embodiment of the disclosure.

### DESCRIPTION OF THE EMBODIMENTS

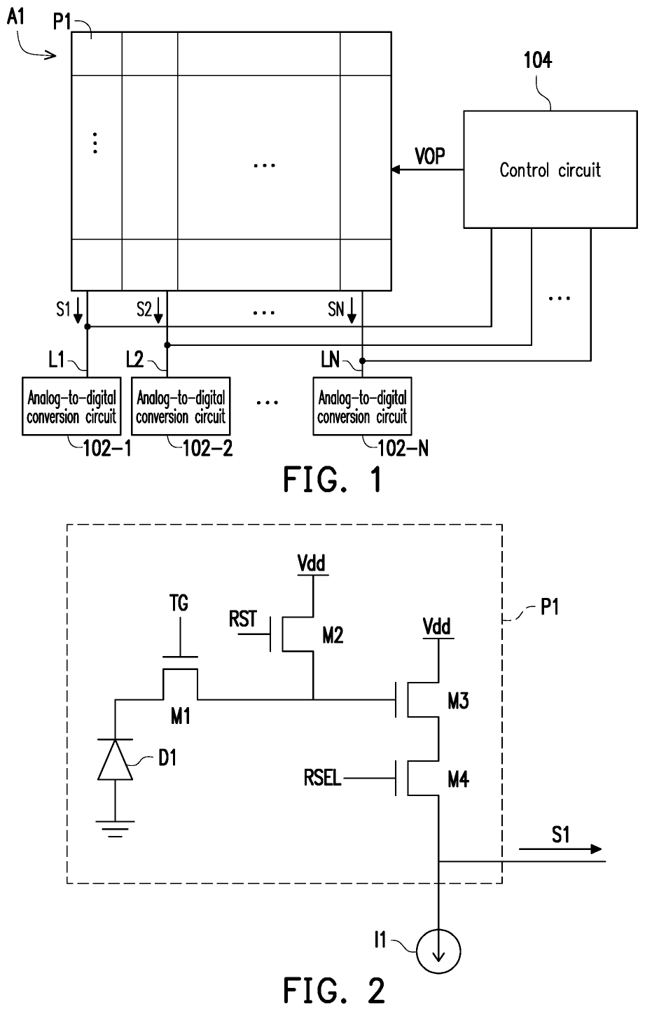

FIG. 1 is a schematic view of a fingerprint sensing apparatus according to an embodiment of the disclosure. Referring to FIG. 1, the fingerprint sensing apparatus includes a sensing pixel array A1, multiple analog-to-digital conversion circuits 102-1˜102-N, and a control circuit 104, where N is an integer greater than 1. The control circuit 104 is coupled to the sensing pixel array A1 and the analog-to-digital conversion circuits 102-1˜102-N. The analog-to-digital conversion circuits 102-1˜102-N are individually coupled to sensing pixels P1 of the first column to an N-th column in the sensing pixel array A1 through corresponding sensing signal lines L1˜LN. The sensing pixel array A1 includes multiple sensing pixels P1, and each of the sensing pixels P1 is coupled to an operation voltage VOP provided by the control circuit 104.

Each of the sensing pixels P1 may sense an optical signal including fingerprint information, and may generate a sensing signal according to the optical signal and the operation voltage VOP. In the embodiment, for example, the selected sensing pixels P1 of the first column to the N-th column in the sensing pixel array A1 may individually output the sensing signals S1˜SN on the corresponding analog-to-digital conversion circuits 102-1˜102-N. The control circuit 104 may adjust a voltage value of the operation voltage VOP according to the sensing signals S1˜SN to enable voltage values of the sensing signals S1˜SN generated by the sensing pixels P1 to fall within a default range. The analog-to-digital conversion circuits 102-1˜102-N may individually convert the sensing signals S1˜SN into digital signals for a back-end circuit (for example, a processor circuit) to perform subsequent fingerprint identification processing.

In this way, the voltage value of the operation voltage VOP is adjusted by the control circuit 104 according to the sensing signals S1˜SN, and the voltage values of the sensing signals S1˜SN are enabled to fall within the default range, which can reduce a global change of the sensing signal voltages resulted from factors such as die-to-die variation, temperature, or the aging of fingerprint sensing apparatus. In this regard, the requirement for a dynamic range of the analog-to-digital conversion circuits 102-1˜102-N is further reduced, and the production cost of the fingerprint sensing apparatus is effectively avoided from increasing. Moreover, since the fingerprint sensing apparatus may improve an available dynamic range of the analog-to-digital conversion circuits through adjusting the voltage values of the sensing signals S1˜SN, the quality requirement for the manufacturing process of a thin film transistor may also be reduced.

Further specifically, a circuit structure of the sensing pixels P1 may be, for example, as shown in FIG. 2. The sensing pixels P1 may include a photoelectric conversion unit D1 and a sensing signal generating circuit composed of a transmission transistor M1, a resetting transistor M2, an amplifying transistor M3, and a selecting transistor M4. The photoelectric conversion unit D1 may be, for example, a photodiode. A positive pole and a negative pole of the photoelectric conversion unit D1 are respectively coupled to a first terminal of the transmission transistor M1 and a ground, a second terminal of the transmission transistor M1 is coupled to a control terminal of the amplifier transistor M3, and a control terminal of the transmission transistor M1 receives a transmission control signal TG. The resetting transistor M2 is coupled between an operation voltage Vdd and the control terminal of the amplifying transistor M3, and a control terminal of the resetting transistor M2 receives a reset control signal RST. A first terminal of the amplifying transistor M3 and a second terminal of the amplifying transistor M3 are respectively coupled to the operation voltage Vdd and a first terminal of the selecting transistor M4, a second terminal of the selecting transistor M4 is coupled to a current source Il and the corresponding analog-to-digital conversion circuit, and a control terminal of the selecting transistor M4 receives a selection control signal RSEL.

The resetting transistor M2 may be controlled by the reset control signal RST to reset a voltage of the control terminal of the amplifying transistor M3 according to the operation voltage. When the row of the sensing pixels P1 is selected to output the sensing signals, the selecting transistor M4 may be controlled by the selection control signal RSEL and is conducted. Then, the transmission transistor M1 is controlled by the transmission control signal TG and is conducted (the resetting transistor M2 is in a disconnected state under the circumstances), and the photoelectric conversion unit D1 transmits an electrical signal, obtained by converting the optical signal including the fingerprint information, to the control terminal of the amplifying transistor M3. A voltage of the electrical signal may decrease in response to an exposure of the photoelectric conversion unit D1, further changing conduction degree of the amplifying transistor M3, and the fingerprint information (in the embodiment, the sensing signal S1 is taken as an example) is output to the analog-to-digital conversion circuits through the selecting transistor M4. In the embodiment, the control circuit 104 may adjust the magnitude of the operation voltage Vdd according to the sensing signal S1 output by the selecting transistor M4, that is, the operation voltage Vdd is to be adjusted as the operation voltage VOP in the embodiment of FIG. 1 to enable a voltage value of the sensing signal S1 to fall within the default range, and the available dynamic range of the analog-to-digital conversion circuits is thereby avoided from being compressed. It is worth noting that in some embodiments, the control circuit 104 may adjust the voltage value of the sensing signal S1 through controlling a voltage of the reset control signal RST, the transmission control signal TG, or the selection control signal RSEL. That is to say, the operation voltage VOP of the embodiment of FIG. 1 may include at least one of the operation voltage Vdd and the controlled voltage values of the reset control signal RST, the transmission control signal TG, and the selection control signal RSEL. The operation voltage VOP of the embodiment of FIG. 1 is not limited to the operation voltage Vdd.

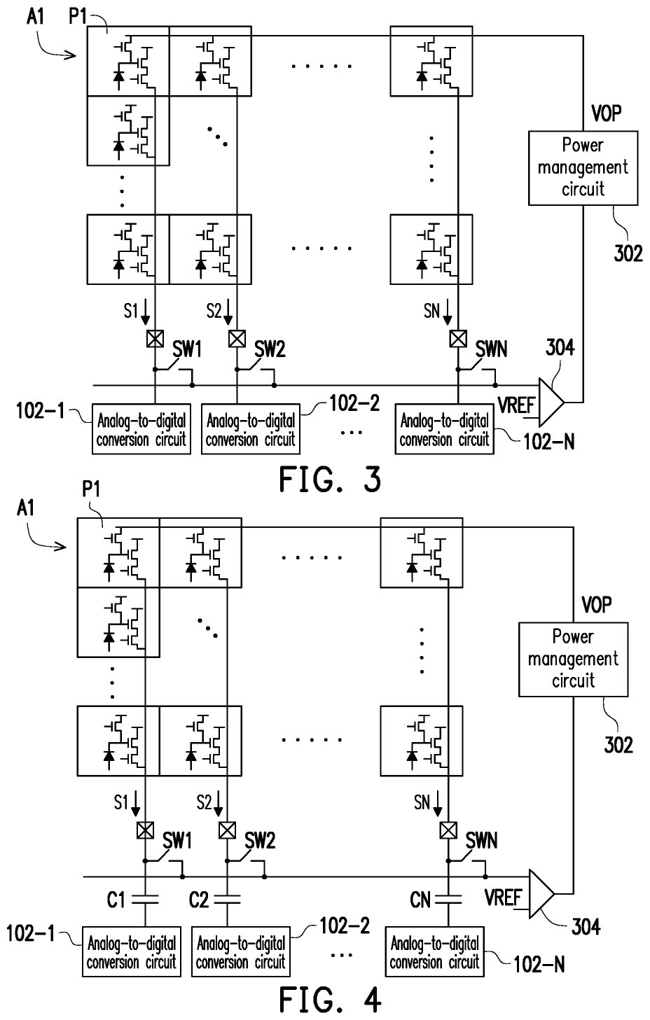

FIG. 3 is a schematic view of a fingerprint sensing apparatus according to another embodiment of the disclosure. Referring to FIG. 3, in the embodiment, the control circuit 104 of the fingerprint sensing apparatus may be implemented by a power management circuit 302, a comparator circuit 304, and multiple switches SW1˜SWN. The power management circuit 302 is coupled to each of the sensing pixels P1 (in FIG. 4, the power management circuit 302 is coupled to the sensing pixels P1 in the first row for illustration) and an output terminal of the comparator circuit 304. The switches SW1˜SWN are individually coupled between one of the input terminals of the comparator circuit 304 and the corresponding sensing signal lines L1˜LN, and an other input terminal of the comparator circuit 304 is coupled to a reference voltage VREF. The power management circuit 302 controls a conduction state of the switches SW1˜SWN to select the voltages of the sensing signals provided by one of the sensing signal lines L1˜LN to compare with the reference voltage VREF. The power management circuit 302 may adjust the operation voltage VOP according to a comparison result of the voltages of the sensing signals S1˜SN and the reference voltage VREF. For example, when the voltages of the sensing signals S1˜SN are all higher than the reference voltage VREF, the power management circuit 302 may adjust the voltage value of the operation voltage VOP according to the comparison result output by the comparator circuit 304 (for instance, gradually decrease a voltage value of the operation voltage Vdd) until the voltages of the sensing signals S1˜SN are all lower than the reference voltage VREF, and the voltage values of the sensing signals are thereby enabled to fall within the default range.

FIG. 4 is a schematic view of a fingerprint sensing apparatus according to another embodiment of the disclosure. Referring to FIG. 4, the difference between the fingerprint sensing apparatus in the embodiment and the fingerprint sensing apparatus in the embodiment of FIG. 3 is that the fingerprint sensing apparatus of the embodiment further includes multiple filter capacitors C1˜CN. The filter capacitors C1˜CN are individually coupled between the corresponding sensing signal lines L1˜LN and the corresponding analog-to-digital conversion circuits 102-1˜102-N. The filter capacitors C1˜CN may filter out direct current components in the sensing signals S1˜SN, the analog-to-digital conversion circuits 102-1˜102-N are thus enabled to perform an analog-to-digital conversion on voltage change results of the sensing signals S1˜SN resulted from the exposure of the photoelectric conversion unit D1, which can further optimize the available dynamic range of the analog-to-digital conversion circuits 102-1-102-N.

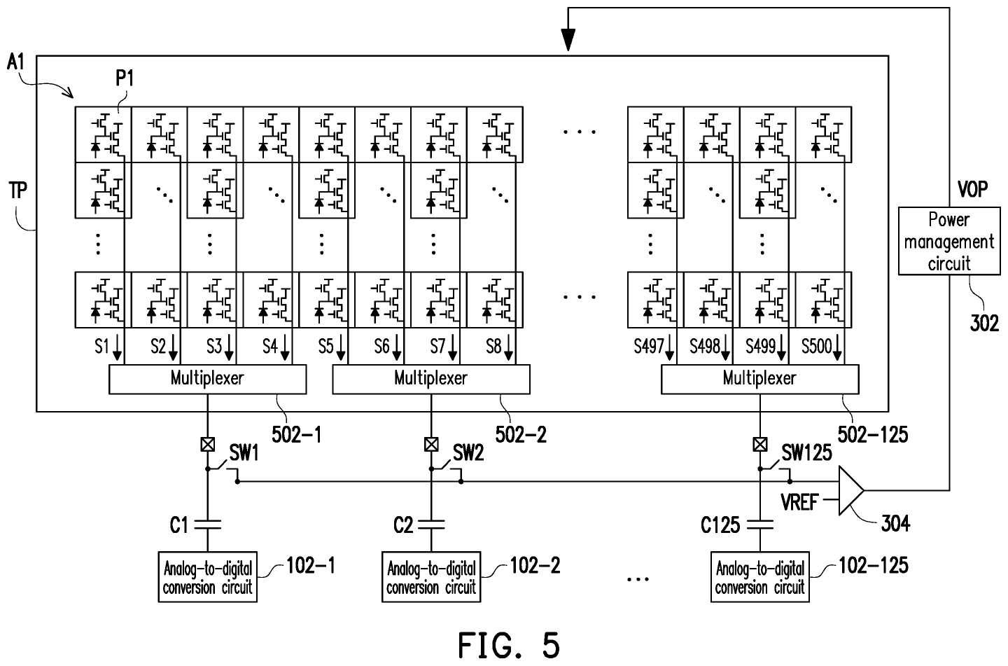

FIG. 5 is a schematic view of a fingerprint sensing apparatus according to another embodiment of the disclosure. Referring to FIG. 5, the difference between the fingerprint sensing apparatus in the embodiment and the fingerprint sensing apparatus in the embodiment of FIG. 4 is that the fingerprint sensing apparatus of the embodiment further includes multiple multiplexers 502-1˜502-125. The multiplexers 502-1˜502-125 may, for example, be disposed on a thin film transistor panel TP with the sensing pixel array A1, but the disclosure is not limited thereto. Each of the multiplexers 502-1˜502-125 is individually coupled to the corresponding sensing signal line and the corresponding filter capacitor, and one of the sensing signals is selected from the corresponding sensing signal lines to be output to the filter capacitors receiving the corresponding sensing signals. For example, the multiplexer 502-1 may select one of the sensing signals S1˜S4 to be output to the filter capacitor C1, and the multiplexer 502-125 may select one of the sensing signals S497˜S500 to be output to the filter capacitor C125 (it is assumed that the number of sensing signal lines is 500 in the embodiment, but the embodiment is not limited thereto). Similarly, the power management circuit 302 may adjust the operation voltage VOP according to the comparison result of the voltages of the sensing signals S1˜SN provided by the multiplexers 502-1˜502-125 with the reference voltage VREF, the filter capacitors C1˜C125 may filter out the direct current components in the sensing signals S1˜SN, and the analog-to-digital conversion circuits 102-1102-125 are enabled to perform the analog-to-digital conversion on the voltage change results of the sensing signals S1˜SN resulted from the exposure of the photoelectric conversion unit D1. Since the details of implementation are similar to the above embodiment, there is no repetition in the embodiment. In this way, the multiplexers 502-1˜502-125 are configured to select the output sensing signals S1˜SN, which can effectively reduce circuit connection nodes and the number of electronic devices in the fingerprint sensing apparatus, thereby reducing the circuit area.

In summary of the above, the control circuit in the embodiment of the disclosure may adjust the voltage value of the operation voltage output to each of the sensing pixels according to the sensing signals to enable the voltage values of the sensing signals generated by each of the sensing pixels to fall within the default range. In this way, the requirement for the dynamic range of the analog-to-digital conversion circuits can be reduced, and the production cost of the fingerprint sensing apparatus can thereby be effectively avoided from increasing. In some embodiments, the fingerprint sensing apparatus may also include the filter capacitors coupled between the sensing signal lines and the analog-to-digital conversion circuits. The filter capacitors can filter out the direct current components in the sensing signals and can further optimize the available dynamic range of the analog-to-digital conversion circuits.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A fingerprint sensing apparatus, comprising:
a sensing pixel array, comprising a plurality of sensing pixels, wherein each of the sensing pixels is coupled to an operation voltage, and each of the sensing pixels senses an optical signal comprising fingerprint information, and generates a sensing signal according to the optical signal and the operation voltage;
a control circuit, coupled to the sensing pixel array, and adjusting a voltage value of the operation voltage according to the sensing signal to enable a voltage value of the sensing signal generated by each of the sensing pixels to fall within a default range; and
a plurality of analog-to-digital conversion circuits, individually coupled to the corresponding sensing pixels through a plurality of corresponding sensing signal lines to convert the sensing signal into a digital signal.

2. The fingerprint sensing apparatus according to claim 1, wherein the control circuit comprises:
a comparator circuit, wherein a first input terminal of the comparator circuit is coupled to the sensing signal lines, a second input terminal of the comparator circuit is coupled to a reference voltage, and the comparator circuit compares the voltage value of the sensing signal with a voltage value of the reference voltage to generate a comparison signal; and
a power management circuit, coupled to an output terminal of the comparator circuit and the sensing pixel array, and adjusting the voltage value of the operation voltage according to the comparison signal.

3. The fingerprint sensing apparatus according to claim 2, wherein the control circuit further comprises:
a plurality of switches, coupled between the corresponding sensing signal lines and the first input terminal of the comparator circuit, wherein each of the switches is controlled by the power management circuit to provide the sensing signal corresponding to the sensing signal lines to the first input terminal of the comparator circuit.

4. The fingerprint sensing apparatus according to claim 2, further comprising:
a plurality of filter capacitors, coupled between the corresponding sensing signal lines and the corresponding analog-to-digital conversion circuits, and filtering out a direct current component in the sensing signal.

5. The fingerprint sensing apparatus according to claim 2, further comprising:
a plurality of multiplexers, wherein an input terminal of each of the multiplexers is coupled to the corresponding sensing signal lines, each of the analog-to-digital conversion circuits is coupled to an output terminal of the corresponding multiplexers, and one of the sensing signals is selected by each of the multiplexers from the sensing signal lines coupled to the input terminal of each of the multiplexers to be output to the corresponding analog-to-digital conversion circuits.

6. The fingerprint sensing apparatus according to claim 5, further comprising:
a plurality of switches, coupled between the output terminal of the corresponding multiplexers and the first input terminal of the comparator circuit, wherein each of the switches is controlled by the control circuit to provide the sensing signal, provided by the corresponding multiplexes, to the first input terminal of the comparator circuit.

7. The fingerprint sensing apparatus according to claim 1, wherein each of the sensing pixels comprises:
a photoelectric conversion unit, sensing the optical signal including the fingerprint information to generate an electrical signal; and
a sensing signal generating circuit, coupled to the photoelectric conversion unit and the operation voltage, and converting the operation voltage into the corresponding sensing signal according to the electrical signal.

8. The fingerprint sensing apparatus of claim 7, wherein each of the sensing signal generating circuits comprises:
a transmission transistor, wherein a first terminal of the transmission transistor is coupled to the photoelectric conversion unit and is controlled by a transmission control signal to output the electrical signal;
a resetting transistor, wherein a first terminal of the resetting transistor is coupled to the operation voltage, a second terminal of the resetting transistor is coupled to a second terminal of the transmission transistor, and the resetting transistor is controlled by a reset control signal to reset a voltage of the second terminal of the transmission transistor;
an amplifying transistor, wherein a control terminal of the amplifying transistor is coupled to the second terminal of the transmission transistor, a first terminal of the amplifying transistor is coupled to the operation voltage, and the sensing signal is generated in response to a voltage value of the electrical signal; and
a selecting transistor, coupled between a second terminal of the amplifying transistor and an output terminal of the sensing signal generating circuit, and controlled by a selection control signal to output the sensing signal.
